(19) United States
(12) Patent Application Publication
(10) Pub. No.: US 2011/0284983 A1
(43) Pub. Date: Nov. 24, 2011

(54) PHOTODIODE DEVICE AND MANUFACTURING METHOD THEREOF

(75) Inventors: Chan Shin WU, Hukou Shiang (TW); Yung-Yi TU, Taichung City (TW); Shan Hua WU, Zhubei City (TW)

(73) Assignee: SOLAPOINT CORPORATION, Hukou Shiang (TW)

(21) Appl. No.: 13/019,194

(22) Filed: Feb. 1, 2011

Related U.S. Application Data
(63) Continuation-in-part of application No. 12/784,961, filed on May 21, 2010.

(30) Foreign Application Priority Data
Dec. 23, 2010 (TW) 099145577

(51) Int. Cl. H01L 31/0203; H01L 31/0224; H01L 31/18

(52) U.S. Cl. 257/434; 438/98; 257/459; 257/E31.117; 257/E31.124

(57) ABSTRACT

A photodiode device and the manufacturing method of the same are provided. The photodiode device includes a substrate; an epitaxy layer on the substrate, the epitaxy layer including a window layer and a cap layer on the window layer, the cap layer covering a portion of the window layer; and a patterned conductive layer on the cap layer, the patterned conductive layer being formed with a bottom area and a top area wherein the bottom area is greater than the top area.

### BACKGROUND OF THE INVENTION

1. Field of the Invention

The invention is related to a photodiode device and the method thereof, especially to a photodiode device having surface conductive layer and the method thereof.

2. Description of the Prior Art

With the advent of the energy shortage, people gradually pay more attention to the techniques of power saving and the development of alternative energy, such as wind energy, water energy, solar energy, etc. Nowadays, the solar cell is widely used in various application fields due to its advantages of low pollution, easy operation, and long lifespan. Solar cell is a photodiode, which is capable of absorbing sunlight by a P-N junction made of different semiconductor materials and converting the energy of sunlight into electricity by the photovoltaic effect.

FIGS. 1A and 1B are drawings, in cross-sectional views, illustrating one conventional process of manufacturing the photodiode. Referring to FIG. 1A, a wafer 100 having a substrate 110 and an epitaxy layer 120 is provided, wherein the epitaxy layer is a multiple layered structure having a layer with a P-N junction 121, a window layer 123 and a cap layer 125 above the P-N junction. A back conductive layer 130 is formed on a bottom surface of the wafer 100 for use as an electrical connection at a later stage. Next, a first patterned conductive layer 140 with a thickness of about 5000 Å is formed on the epitaxy layer 120 by conventional metal deposition, microlithography and etching processes with a first photomask.

Next, referring to FIG. 1B, the window layer 123 is exposed by etching the cap layer 125 of the epitaxy layer 120 using the first patterned conductive layer 140 as a mask. A second patterned conductive layer 150 is then formed on the first patterned conductive layer 140 by an electroplating method with a second photomask, so as to increase the thickness of the whole conductive layer. Typically, the thickness of the second patterned conductive layer 150 is about 5-6 μm. Lastly, a conformal anti-reflective layer (not shown) can be formed on the wafer 100.

Conventional methods such as those of FIG. 1A and FIG. 1B have many disadvantages. For example, they require at least two photo masks to form the first and second patterned conductive layers 140 and 150, which would be considered high-cost. Besides, they also have alignment problems, which would adversely cause an undesired structure as shown in FIG. 1B. Therefore, it is necessary to provide a novel structure and method for a photodiode device in order to resolve the problems of the conventional technology.

### SUMMARY OF THE INVENTION

In light of the drawbacks of the prior arts, the present invention provides a photodiode device and the method thereof, which can improve photoelectric transformation efficiency, enhance the reliability of the manufacturing process, and reduce production costs.

In one aspect, the present invention provides a photodiode device comprising a substrate; a epitaxy layer on the substrate, the epitaxy layer having a window layer and a cap layer covering a portion of the window layer; and a patterned conductive layer on the cap layer, wherein the patterned conductive layer being formed with a bottom area and a top area, wherein the bottom area is greater than the top area.

The present invention also provides a photodiode device as described above, wherein the patterned conductive layer is further characteristic in no footing structure horizontally extending from the bottom of the patterned conductive layer in a thickness equal to or less than one fifteenth of a thickness of the patterned conductive layer.

In another aspect, the present invention provides a method of manufacturing a photodiode device. The method comprises providing a wafer having a substrate and an epitaxy layer, the epitaxy layer having a window layer and a cap layer on the window layer; depositing a patterned conductive layer on the epitaxy layer, the patterned conductive layer having a footing structure horizontally extending from the bottom of the patterned conductive layer, the footing structure having a thickness equal to or less than one fifteenth of a thickness of the patterned conductive layer; removing at least a portion of the footing structure; and etching a portion of the cap layer to expose the window layer.

The present invention also provides a method as described above, further comprising using an evaporation process to make the patterned conductive layer formed with a bottom area and a top area, wherein the bottom area is greater than the top area.

The other aspects of the present invention, part of them will be described in the following description, part of them will be apparent from description, or can be known from the execution of the present invention. The aspects of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying pictures, wherein:

FIGS. 1A and 1B are drawings, in cross-sectional views, illustrating one conventional process of manufacturing a photodiode device;

FIGS. 2A to 2F and 2B′ are drawings, in cross-sectional views, illustrating a process of manufacturing a photodiode device in accordance with one embodiment of the present invention;

FIGS. 3A to 3E are drawings, in cross-sectional views, illustrating a process of manufacturing a photodiode device in accordance with one embodiment of the present invention;

FIG. 4 is a drawing in a cross-sectional view, illustrating a photodiode device in accordance with one embodiment of the present invention.

FIGS. 5A and 5B are scanning electron microscope (SEM) images showing footing structures of a semi-product of a photodiode device in accordance with one embodiment of the present invention.

FIG. 6 is a scanning electron microscope (SEM) image showing a semi-product of a photodiode device in accordance with one embodiment of the present invention.

### DETAILED DESCRIPTION OF THE EMBODIMENTS

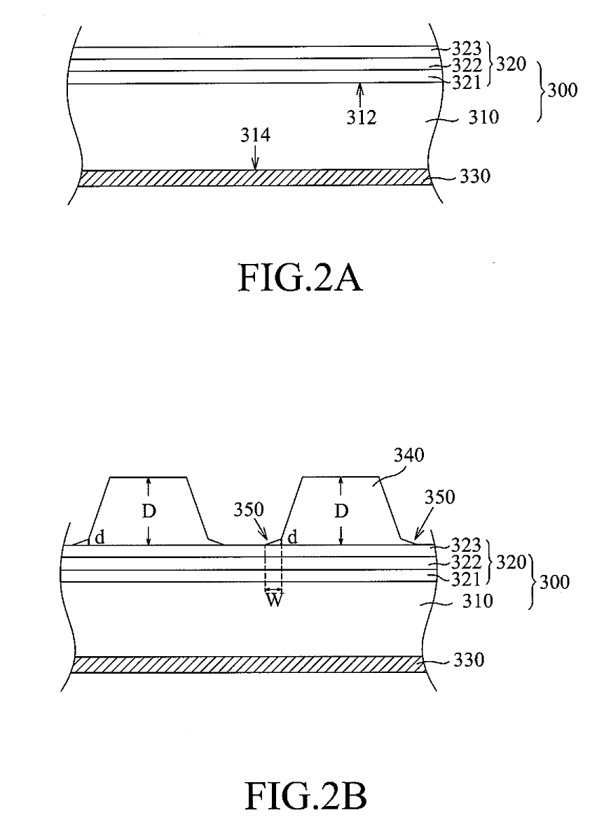

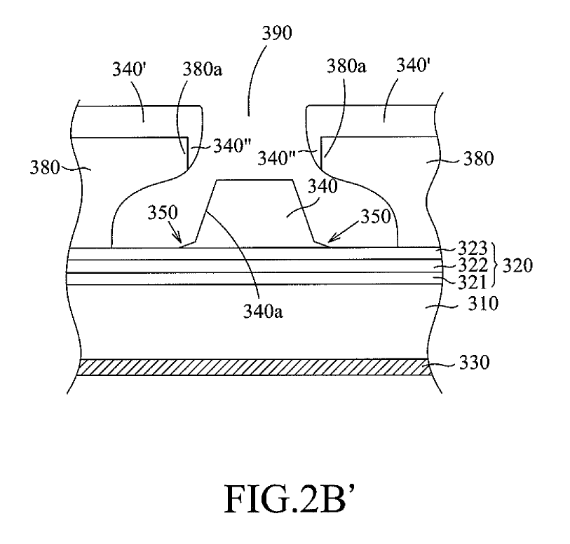

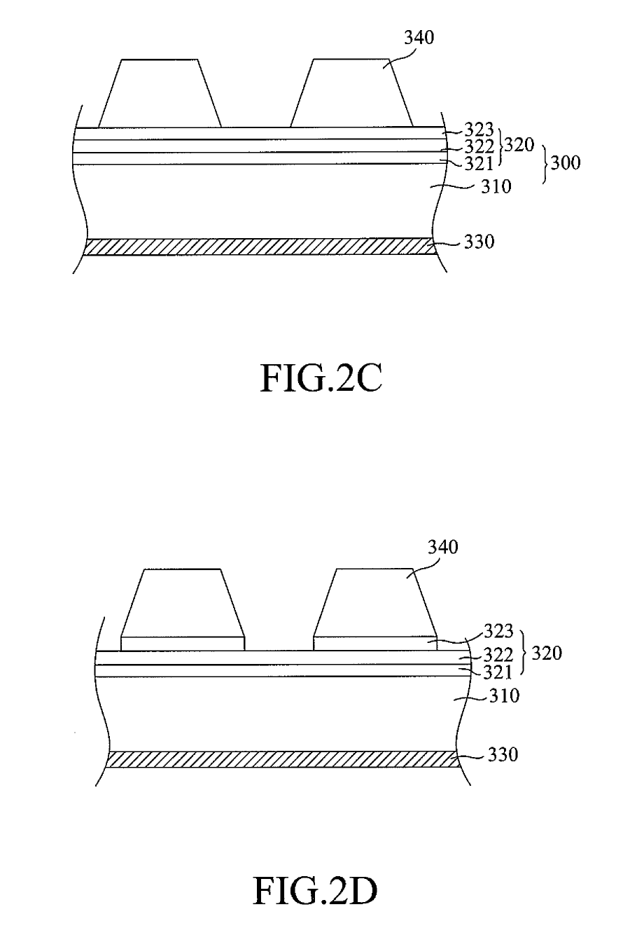

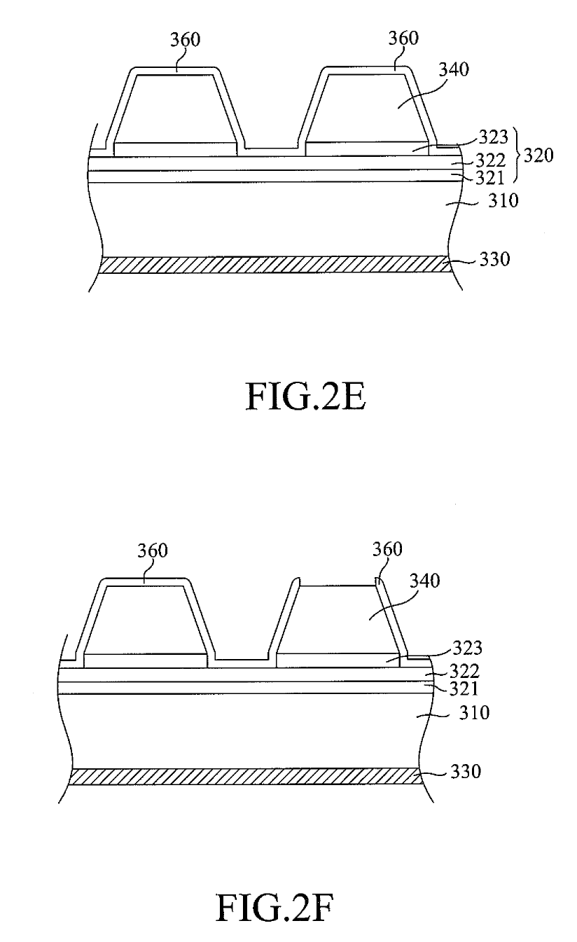

The photodiode device and the related manufacturing methods disclosed in the present invention have advantages of increasing photoelectric transformation efficiency, reducing the number of required photo masks, and lowering the production cost. To make the disclosure of the present invention more detailed and complete, references are made to the following description in conjunction with FIG. 2A to FIG. 6. However, the drawings illustrated in the figures are not necessarily to scale and only intended to serve as illustrating embodiments of the invention, and the devices, elements, or operations in the following embodiments are provided for exemplary purposes only. In the following description, the unnecessary structure, material, procedures or steps that may make the subject matter of the present invention obscure will be omitted. Furthermore, it should be noted that when an element is referred to as being “on” another element, it can be directly on the other element or intervening elements may also be present, unless explicitly defined otherwise herein.

In the embodiments of the present invention, each layers on the epitaxy layer of the substrate can be formed by any deposition method well known by those skilled in the art, such as chemical vapor deposition process, plasma enhanced chemical vapor deposition (PECVD) process, evaporation, plating, atomic layer deposition (ALD) process, etc.

FIGS. 2A-2F are drawings, in cross-sectional views, illustrating a process of manufacturing a photodiode in accordance with one embodiment of the present invention. Referring to FIG. 2A, in one embodiment of the present invention, a wafer 300, which has a substrate 310 and an epitaxy layer 320 formed on a first surface 312 of the substrate 310, is provided. The substrate 310 can be any suitable semiconductor substrate, such as silicon substrate, germanium substrate, GaAs substrate, etc. The epitaxy layer 320 is a multiple layered structure having at least one P-N junction, which is made of several different semiconductor materials having desirable lattice matching conditions and energy gaps. Any suitable known film process, such as MOCVD (Metal-Organic Chemical Vapor Deposition) or MBE (Molecular Beam Epitaxy), can form the epitaxy layer 320. In the embodiment, the epitaxy layer 320 include a multiple layered structure 321, a window layer 322 and a cap layer 323 on the top of the multiple layered structure 321. The multiple layered structure 321 includes tunnel layers interleaved between a plurality of P-N junctions respectively, for effectively collecting the photo-induced current.

Typically, the plurality of P-N junctions included in the epitaxy layer 320 are made of different semiconductor materials having different energy gaps for absorbing light beams of different wavelengths. For example, the epitaxy layer 320 can include a GaInP layer, a GaAs layer, and a GaInAs layer. In one embodiment, the P-N junction being closer to the substrate has a smaller energy gap than the P-N junction being further from the substrate, which can be used to absorb light of shorter wavelength. With these P-N junctions having different energy gaps, the absorption wavelength range can be widened, so as to improve the photoelectric transformation efficiency.

Next, a back conductive layer 330 is formed on a second surface 314 of the substrate 310, which can be formed of any suitable metal materials, such as Ti, Ag, Pt, Au, Sn, Ni, Cu, alloys thereof, or other suitable electrically conductive materials. The first conductive layer 330 can be formed by printing method or any vacuum plating techniques.

Referring to FIG. 2B, a patterned conductive layer 340 is formed on the epitaxy layer 320. The patterned conductive layer 340 can be made of any suitable electrically conductive materials, such as a metal or a metallic alloy, and is of a thickness which ranges preferably between 4 μm and 8 μm, but the aforesaid disclosure should not limit the present invention. The patterned conductive layer 340 is a multiple layered structure. In this embodiment, the patterned conductive layer 340 comprises a bottom contact layer in direct contact with the epitaxy layer 320; a middle conductive layer disposed on the bottom contact layer; an upper conductive layer disposed on the middle conductive layer; and a top barrier layer disposed on the upper conductive layer. In other embodiments, it is feasible for the patterned conductive layer 340 to be composed of only two of the aforesaid layers. In other embodiments, in addition to the aforesaid layers, the patterned conductive layer 340 includes another layer that manifests a function not disclosed above.

A conventional metal deposition process, such as an evaporation process in this embodiment, can form the patterned conductive layer 340. As shown in FIG. 2B′, a patterned photoresist 380 is formed on the epitaxy layer 320, but leaving exposed an opening 390 intended for deposition of the patterned conductive layer 340. In this embodiment, the patterned photoresist 380 is a negative-typed photoresist, and is preferably between 9 μm and 12 μm thick. Preferably, the top of the negative-typed photoresist is not connected to the top of the patterned conductive layer 340 intended to be formed. The patterned photoresist 380 is subject to irradiation and development and thus is undercut as shown in FIG. 2B′. Then, an electrically conductive material is deposited, by evaporation, in the opening 390 to form the patterned conductive layer 340 on the epitaxy layer 320. Afterward, the patterned photoresist 380 and redundant conductive material 340′, 340″ thereon are removed by way of a lift-off process, as shown in FIG. 2B. In this embodiment, the patterned conductive layer 340 is a multiple layered structure formed by depositing different materials on the epitaxy layer under the same mask (i.e., the patterned photoresist 380). For example, the bottom contact layer is made of Ge, Ni, Pd, or alloys thereof. The middle conductive layer is made of Ag. The upper conductive layer is made of Au, Mo, or alloys thereof. The top barrier layer is made of Ni, W, Mo, Ti, Ta, oxides of the aforesaid materials, or combinations thereof.

The thickness and shape of the patterned conductive layer 340 depend on the duration and position of evaporation. Referring to FIG. 2B′, during evaporation, the conductive layer 340″ is gradually deposited on an edge 380a of the patterned photoresist 380 near the opening 390, such that the size of the opening 390 decreases with duration of evaporation. In so doing, the available area for accumulating the conductive material gradually decreases during evaporation, so as to form a structure of a trapezoidal cross-section as shown in FIGS. 2B and 2B′. The patterned conductive layer 340 is formed with a bottom area positioned proximate to the epitaxy layer 320 and a top area positioned distal to the epitaxy layer 320, wherein the bottom area is greater than the top area.

Referring to FIGS. 2B and 2B′, a footing structure 350 may be formed at the bottom of the patterned conductive layer 340 because of evaporation or another process. The footing structure 350 resulted from accumulation of the electrically conductive material extends from the bottom of the patterned conductive layer 340 along the horizontal direction of the substrate 310. In this embodiment, the footing structure 350 is formed mainly because, during evaporation, the electrically conductive material hits a sidewall 340a of the patterned conductive layer 340, rebounds off the sidewall 340a, and lands on the surface of the epitaxy layer 320 to accumulate thereon. The thickness of the patterned conductive layer 340 thus evaporated increases with the process duration. The thicker the patterned conductive layer 340 is, the thicker and firmer the footing structure 350 is. In this embodiment, the middle conductive layer is the thickest one. Hence, the major constituent element of the footing structure 350 is the material of which the middle conductive layer is formed, such as silver. In general, the thickness d of the footing structure 350 is equal to or less than one fifteenth of the thickness D of the patterned conductive layer 340. The patterned conductive layer 340 of the thickness D between 4 μm and 8 μm can form the footing structure 350 of the thickness d between 1000 Å and 5000 Å and of the width w between 1 μm and 2 μm. In this embodiment, the footing structure 350 is formed by evaporation. In other embodiments, different deposition processes can also form the footing structure.

Referring to FIG. 2C, the wafer 300 is etched to remove the footing structure 350, using any appropriate etching method, such as drying etching, wet etching, physical ion etching, chemical ion etching, or a combination of physical and chemical ion etching. Taking the dry etching as an example, dry etching is performed under a pressure between 10 mTorr and 30 mTorr, with a power level between 100 Watt and 500 Watt, a DC bias between 300V and 600V, and a flow rate of an inert gas between 15 sccm and 25 sccm. The inert gas is one selected from the group consisting of Helium (He), Neon (Ne), Argon (Ar), Krypton (Kr), Xenon (Xe), Radon (Rn), and a combination thereof. In this embodiment, the inert gas is Argon (Ar), which forms plasma for bombarding the footing structure 350 to effectuate elimination thereof. In other embodiments, the inert gas is Argon (Ar), Helium (He), or a combination of Argon (Ar) and Helium (He). In some embodiments, wet etching is employed. The footing structure 350 can be removed by a wet etching process of a short duration especially in case of a large difference in dimensions between the footing structure 350 and the patterned conductive layer 340. In some embodiments, the footing structure 350 is removed as much as possible; in some embodiments, only a portion of the footing structure 350 is removed.

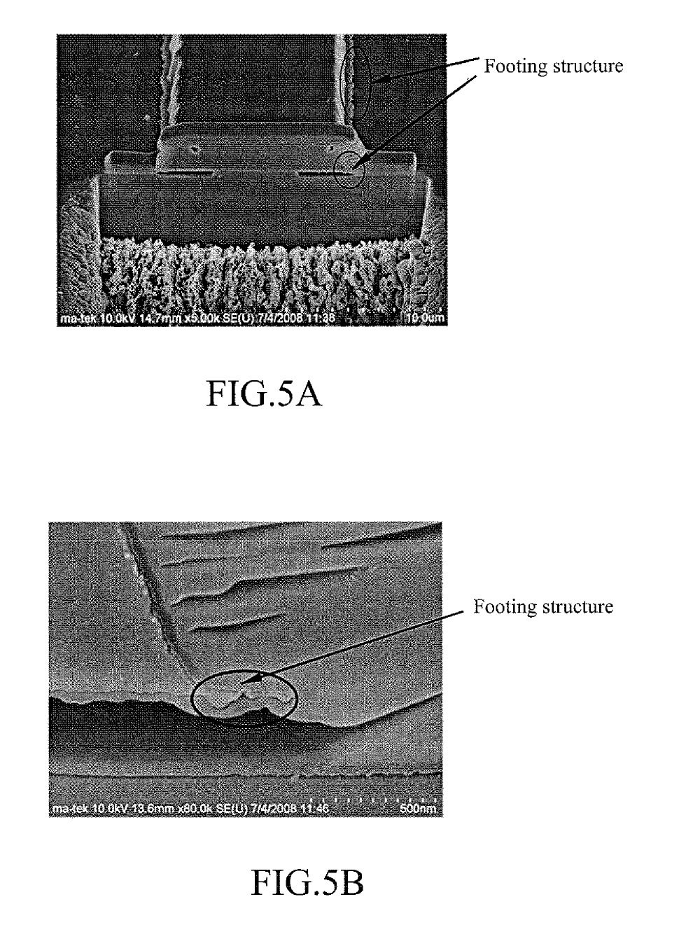

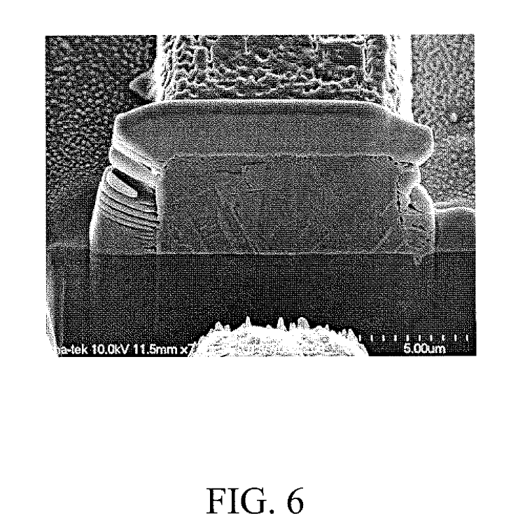

In this embodiment, an etchant for removing the footing structure 350 is a material of an extremely low etching rate with respect to the top barrier layer (i.e., Ni, W, Mo, Ti, Ta, oxides thereof, or combinations thereof) of the patterned conductive layer 340. Hence, in this embodiment, the top barrier layer protects the patterned conductive layer 340 in a dry etching process. In addition, please refer to scanning electron microscope (SEM) images produced during the implementation of the present invention for the footing structure. FIGS. 5A and 5B are scanning electron microscope (SEM) images showing footing structures of a semi-product of a photodiode device during a fabrication process in accordance with an embodiment of the present invention. FIG. 6 is a scanning electron microscope (SEM) image showing a semi-product of a photodiode device after removal of the footing structures therefrom during a fabrication process in accordance with an embodiment of the present invention.

Referring to FIG. 2D, the patterned conductive layer 340 is used as a mask for etching the epitaxy layer 320 to remove a portion of the cap layer 323 so as to expose the window layer 322 thereunder. The epitaxy layer 320 can be etched by a dry etching process or a wet etching process. Taking the wet etching process as an example, an etching solution is a NH₄OH solution, a mixture of H₃PO₄, H₂O₂, and H₂O in a specific proportion, or a citric acid-containing solution. The wet etching enables the residual cap layer 323 to have an undercut (not shown) relative to the patterned conductive layer 340 lying above.

Referring to FIG. 2E, an anti-reflective layer 360 is conformally formed on the patterned conductive layer 340. The anti-reflective layer 360 decreases the amount of light being reflected, and enhances the efficiency of photoelectric conversion. The anti-reflective layer 360 is made of a transparent material of a refractive index lower than the substrate 310, such as SiOₓ, SiNₓ, TiOₓ, or AlOₓ, or a single-layered or double-layered structure that comprises one or more of the aforesaid materials. The thickness of the anti-reflective layer 360 is adjustable as needed or according to the refractive index of a material of which the anti-reflective layer 360 is made. The anti-reflective layer 360 is formed by a conventional deposition technique, such as evaporation, sputtering, chemical vapor deposition, etc.

Referring to FIG. 2F, a portion of the anti-reflective layer 360 is removed by a conventional exposure photolithography process to expose the underlying patterned conductive layer 340 for use in the subsequent electrical connection. This step is fit for use in forming a bus structure on the surface of a photodiode device. For example, the step of removing a portion of the anti-reflective layer 360 includes: coating a photoresist (not shown) on the anti-reflective layer 360; patterning the photoresist by a pattern transfer technique, such as exposure and development, so as to define the position of the patterned conductive layer 340 to be exposed; and etching the anti-reflective layer 360 by means of the patterned photoresist functioning as a mask to obtain the structure shown in FIG. 2F.

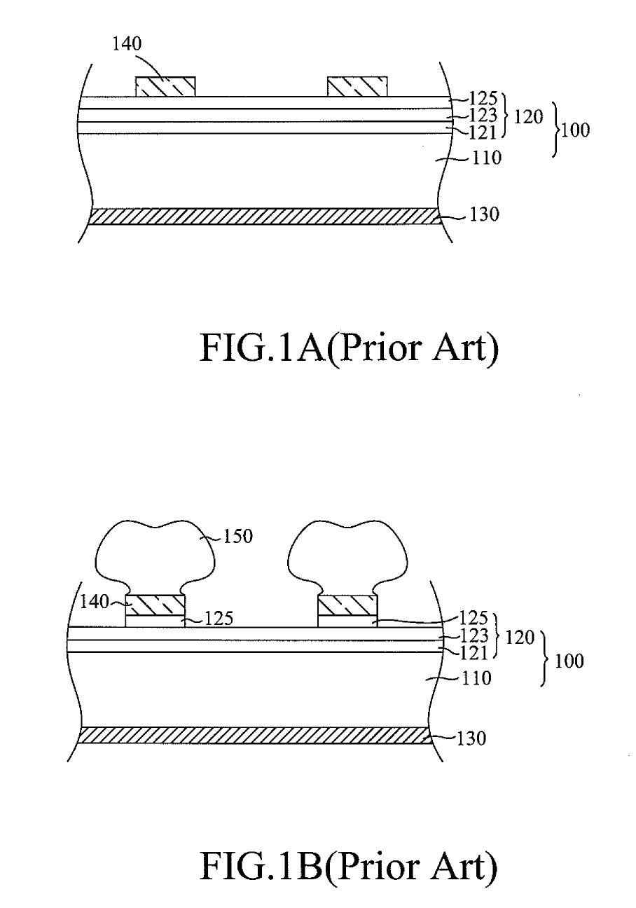

A photodiode device shown in FIG. 2A through FIG. 2F according to an embodiment of the present invention at least has the following advantages. First, the photodiode device reduces its footing structure that has an adverse effect upon the efficiency of photoelectric conversion. Second, the patterned conductive layer 340 need not be formed by two mask fabrication processes depicted in FIG. 1B but is formed by means of only one mask, and thus the fabrication process of the patterned conductive layer 340 according to one embodiment of the present invention is simpler than the conventional ones and thereby effective in reducing fabrication costs. Furthermore, the patterned conductive layer 340 is of a trapezoidal structure formed with a bottom area and a top area, wherein the bottom area is greater than the top area, and thus the trapezoidal structure of the patterned conductive layer 340 is favorable to enhancement of the efficiency of photoelectric conversion, because the trapezoidal structure decreases the amount of lights being blocked from entry.

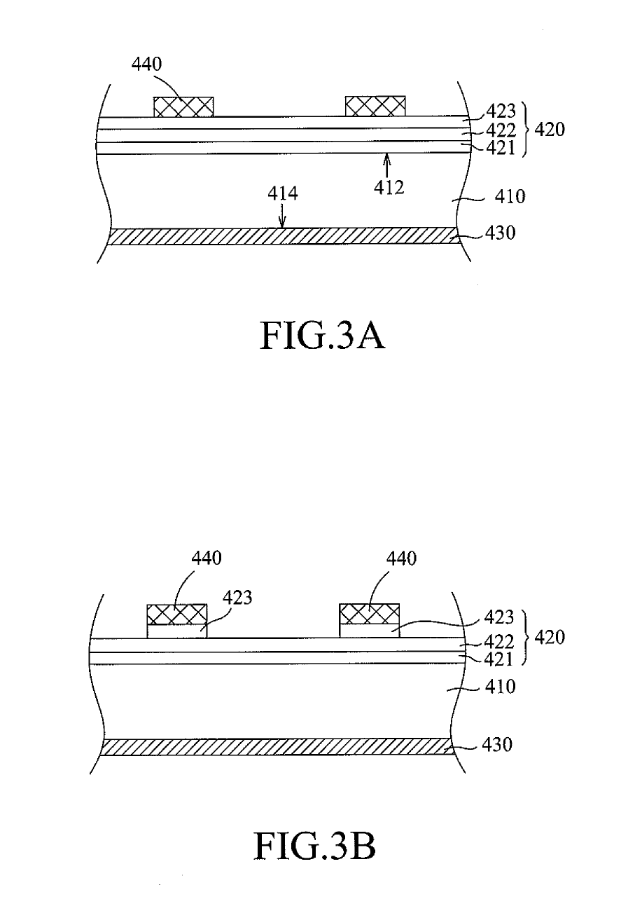

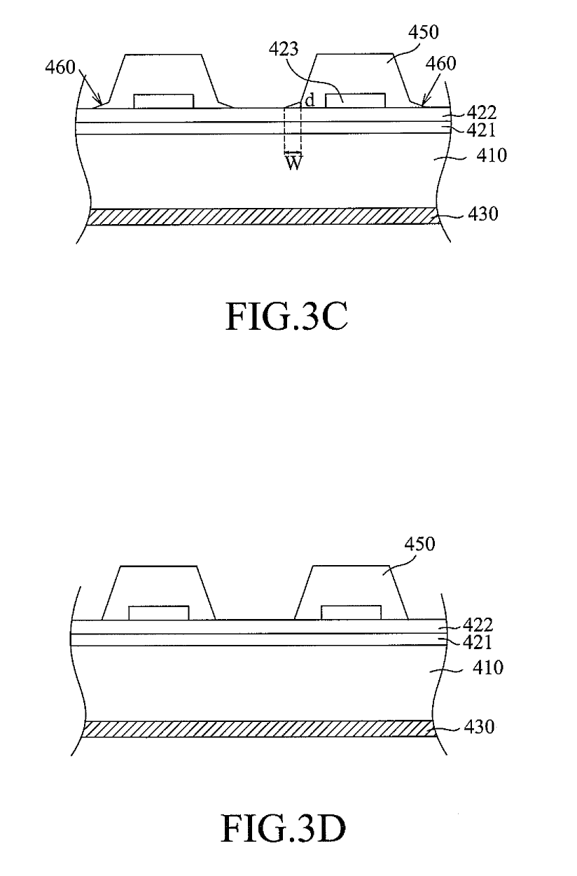

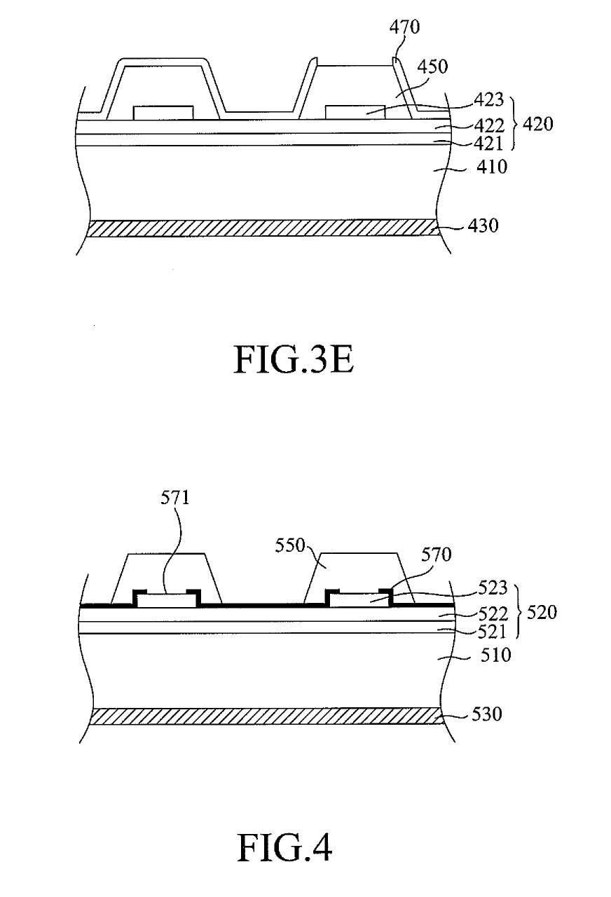

Referring to FIG. 3A through FIG. 3E, there are shown cross-sectional views of the process flow of the fabrication of a photodiode according to another embodiment of the present invention. The embodiment illustrated with FIG. 3A through FIG. 3E is different from the preceding embodiment. In the preceding embodiment, a patterned conductive layer is formed first, and then the underlying cap layer of the epitaxy layer is etched using the patterned conductive layer as a mask. In the embodiment illustrated with FIG. 3A through FIG. 3E, the cap layer of the epitaxy layer beneath a mask is etched first, and then the patterned conductive layer is formed.

Referring to FIG. 3A, provided in an embodiment of the present invention is a wafer 400 that comprises a substrate 410 and an epitaxy layer 420 on a first surface 412 of the substrate 410. Please refer to the above description for the structures and materials of the substrate 410 and the epitaxy layer 420. Afterward, a back conductive layer 430 is formed on a second surface 414 of the substrate 410 by printing or vacuum coating. Then, a patterned photoresist 440 is formed on the epitaxy layer 420 for defining the position of an etched portion of the epitaxy layer 420. The patterned photoresist 440 is formed, for example, by coating a photoresist (not shown) on the epitaxy layer 420 fully, and then performing a pattern transfer technique, such as exposure and development, on the patterned photoresist, so as to form the patterned photoresist 440 shown in FIG. 3A.

Referring to FIG. 3B, a cap layer 423 of the epitaxy layer 420 is etched using the patterned conductive layer 440 as a mask, so as to expose an underlying window layer 422. Please refer to the above related description for a method of etching the epitaxy layer 420. Referring to FIG. 3C, after the removal of the patterned photoresist 440, a patterned conductive layer 450 is formed to at least cover a plurality of said cap layers 423. The patterned conductive layer 450 is formed, by a photolithographic technique, such as spin coating, exposure and development, in the following steps: forming a patterned photoresist (not shown) on the substrate 410, wherein the patterned photoresist does not cover the cap layer 423; forming a conductive layer for covering the patterned photoresist and the cap layer 423 by a conventional metal deposition process, such as evaporation; and removing, by way of a lift-off process, the patterned photoresist and a portion of redundant conductive layer on the patterned photoresist so as to obtain the patterned conductive layer 450 shown in FIG. 3C. The patterned conductive layer 450 is of a trapezoidal cross-section, such that the patterned conductive layer 450 is formed with a top area positioned distal to the epitaxy layer 420 and a bottom area positioned proximate to the epitaxy layer 420, wherein the bottom area is greater than the top area. As mentioned earlier, the formation of the patterned conductive layer 450 inevitably results in the formation of a footing structure 460 due to a limitation of a fabrication process. In general, the thickness d of the footing structure 460 is equal to or less than one fifteenth of the thickness D of the patterned conductive layer 450. In this embodiment, the footing structure 460 is of the thickness d between 1000 Å and 5000 Å and of the width w between 1 μm and 2 μm. The patterned conductive layer 450 can be made of any suitable electrically conductive material, and is between 4 μm and 8 μm thick, but the aforesaid disclosure does not limit the present invention.

Referring to FIG. 3D, the wafer 400 is etched by an etching method described in the preceding embodiment, so as to remove the footing structure 450. However, referring to FIG. 3E, a patterned anti-reflective layer 470 is formed on the substrate 410. A portion of the patterned conductive layer 450 is selectively exposed from the patterned anti-reflective layer 470 for use in electrical connection of a bus structure subsequently fabricated. A method for forming the patterned anti-reflective layer 470 comprises the steps of: forming a conformal anti-reflective layer (not shown) fully by a conventional deposition process, wherein its material and other details are described above; forming a patterned photoresist on a conformal anti-reflective layer, so as to define the position of the patterned conductive layer 450 to be exposed; and etching the conformal anti-reflective layer by means of the patterned photoresist functioning as a mask to obtain the patterned anti-reflective layer 470 shown in FIG. 3E.

The embodiment illustrated with FIG. 3A through FIG. 3E has a drawback: the fabrication process of the patterned conductive layer 450 is likely to damage the window layer 422 exposed from beneath. Hence, in another embodiment, upon completion of etching the cap layer and thereby exposing the window layer, an anti-reflective layer is formed to cover the window layer and a portion of the cap layer and thereby effectuate protection thereof, and then the patterned conductive layer is formed. The structure shown in FIG. 4 comprises a substrate 510 and the epitaxy layer 520 above the substrate 510. The epitaxy layer 520 comprises a cap layer 523 and a window layer 522. The structure shown in FIG. 4 further comprises: an anti-reflective layer 570 covering the window layer 522; a portion of the cap layer 523; and a patterned conductive layer 550 disposed on the cap layer 523, wherein the patterned conductive layer 550 is electrically connected to the cap layer 523 through an opening 571 of the anti-reflective layer 570. Please refer to the preceding embodiments for the fabrication process of the patterned conductive layer 550.

While this invention has been described with reference to the illustrative embodiments, these descriptions should not be construed in a limiting sense. Various modifications of the illustrative embodiment, as well as other embodiments of the invention, will be apparent upon reference to these descriptions. It is therefore contemplated that the appended claims will cover any such modifications or embodiments as falling within the true scope of the invention and its legal equivalents.

1. A method of manufacturing a photodiode device, comprising:
providing a wafer having a substrate and an epitaxy layer, the epitaxy layer having a window layer and a cap layer on the window layer;
depositing a patterned conductive layer on the epitaxy layer, the patterned conductive layer having a footing structure horizontally extending from the bottom of the patterned conductive layer, the footing structure having a thickness equal to or less than one fifteenth of a thickness of the patterned conductive layer; and
removing a portion of the footing structure.

2. The method of claim 1, wherein the patterned conductive layer is a multiple layered structure, the multiple layered structure being formed by depositing different materials on the epitaxy layer under only one mask.

3. The method of claim 2, wherein the mask is a negative-typed photoresist, and the method further comprises removing the mask and conductive materials deposited on the mask by way of a lift-off process after the patterned conductive layer is deposited.

4. The method of claim 3, wherein the negative-typed photo resist is between 9 μm and 12 μm thick, and the patterned conductive layer is between 4 μm and 8 μm thick.

5. The method of claim 1, wherein the step of depositing the patterned conductive layer further comprising using an evaporation process to make the patterned conductive layer formed with a bottom area and a top area, wherein the bottom area is greater than the top area.

6. The method of claim 2, wherein the step of depositing the patterned conductive layer further comprising:
forming an opening within the mask, the opening exposing the epitaxy layer;
depositing materials of the patterned conductive layer on the epitaxy layer; and
gradually reducing the size of the opening by gradually depositing the materials on an edge of the mask, the edge being near the opening.

7. The method of claim 1, wherein the patterned conductive layer further comprises a top barrier layer for protecting the patterned conductive layer when the step of removing a portion of the footing structure is performed using drying etching.

8. The method of claim 1, wherein the step of removing the footing structure is performed by dry etching with a flow rate of an inert gas ranging from about 15 sccm to about 25 sccm under a pressure between 10 to 30 mTorr.

9. The method of claim 8, wherein the dry etching is performed with a power level between about 100 Watts and about 500 Watts and a DC bias between about 300 volts and about 600 volts.

10. The method of claim 1, wherein the step of etching a portion of the cap layer is performed before the step of depositing the patterned conductive layer.

11. A photodiode device made by a method according to one of claims 1-10.

12. A photodiode device, comprising,
a substrate;
a epitaxy layer on the substrate, the epitaxy layer having a window layer and a cap layer covering a portion of the window layer; and
a patterned conductive layer on the cap layer, wherein the patterned conductive layer being formed with a bottom area and a top area, wherein the bottom area is greater than the top area.

13. The photodiode device of claim 12, wherein the patterned conductive layer on the epitaxy layer is characteristic in no footing structure horizontally extending from the bottom of the patterned conductive layer in a thickness equal to or less than one fifteenth of a thickness of the patterned conductive layer.

14. The photodiode device of claim 12, wherein the patterned conductive layer is a multiple layered structure, the multiple layered structure being formed by depositing different materials under only one mask.
